(19) United States
(12) Patent Application Publication
(10) Pub. No.: US 2025/0079130 A1
(43) Pub. Date: Mar. 6, 2025

(54) STRUCTURAL MEMBER

(71) Applicant: TOTO LTD., Fukuoka (JP)

(72) Inventors: Ryunosuke NAKAGAWA, Fukuoka (JP); Tatsuya KOGA, Fukuoka (JP)

(73) Assignee: TOTO LTD., Fukuoka (JP)

(21) Appl. No.: 18/816,038

(22) Filed: Aug. 27, 2024

(30) Foreign Application Priority Data
Aug. 28, 2023 (JP) 2023-137699

(51) Int. Cl. H01J 37/32; C23C 24/04

(52) U.S. Cl. CPC H01J 37/32495; C23C 24/04; H01J 2237/334

(57) ABSTRACT

A structural member 10 includes a base material 100 and a protective film 200 covering a surface 110 of the base material 100. A particle 300 that is harder than the protective film 200 is dispersedly arranged inside the protective film 200.

### CROSS-REFERENCE TO RELATED APPLICATION

This application is based upon and claims the benefit of priority from Japanese Patent Application No. 2023-137699 filed on Aug. 28, 2023, the entire contents of which are incorporated herein by reference.

### BACKGROUND

### Field of the Invention

The present invention relates to a structural member.

### Description of the Related Art

Structural members having a protective film on a surface of a base material are used in various fields such as semiconductor manufacturing apparatus. For example, as described in Japanese Patent Laid-Open No. 2007-321183, in a semiconductor manufacturing apparatus, a protective film is formed on a surface of a base material constituting an inner wall of a chamber in order to protect the base material from plasma.

### SUMMARY

The protective film is deposited on the surface of the base material using a deposition method such as an aerosol deposition method. Thereafter, a surface of the protective film is then polished to adjust it for its flatness. At this time, a residual stress caused by polishing may remain at a surface layer portion of the protective film. Such a residual stress can cause lowering of durability of the protective film and generation of particles. Therefore, after the surface of the protective film has been polished, it is preferable that the surface layer portion of the surface undergoes soft polishing to release the residual stress. The “soft polishing” herein refers to polishing the surface of the protective film with as little residual stress generated as possible, for example, by using a soft member such as polishing cloth or by chemical etching.

A thickness of the surface layer portion to be removed by soft polishing is very thin, which is as thin as 100 nm at most. When a thickness thicker than this is removed, durability of the protective film is needlessly lowered, which is not preferable. Therefore, upon performing soft polishing, it is necessary to perform the polishing while confirming how much thickness has been removed from the surface of the protective film each time.

As a method for confirming a thickness removed, there is considered to be a method for measuring the entire thickness of the protective film each time using, for example, a spectroscopic reflectometry film thickness meter to calculate the amount of change. However, it is difficult to accurately measure a change in thickness as thin as 100 nm or less using the spectroscopic reflectometry film thickness meter. Therefore, upon performing soft polishing, a surface layer portion of the protective film has had to be excessively removed in excess of the minimum thickness to be removed.

The present invention was made in view of these problems, and an object of the present invention is to provide a structural member capable of preventing a surface of a protective film from being polished more than necessary upon manufacturing.

In order to solve the aforementioned problem, the structural member according to the present invention includes a base material and a protective film covering a surface of the base material. A high-hardness particle that is harder than the protective film is dispersedly arranged inside the protective film.

When the protective film with such a configuration undergoes soft polishing, high-hardness particles exposed on a surface of the protective film remain almost unremoved, so that the high-hardness particles are in the state of protrusion from the surface of the protective film. In this case, the amount of protective film removed is generally the same as the protruding amount of high-hardness particles.

The protruding amount of high-hardness particle can be measured relatively easily and precisely using a measuring apparatus such as an electric micrometer, for example. Therefore, performing soft polishing while measuring the protruding amount, i.e., the amount of removal, each time, allows a surface layer portion to be removed as much as necessary. In other words, it is possible to prevent the surface of the protective film from being polished more than necessary.

After a structural member was attached to an etching apparatus or the like, and a surface of a protective film has been deteriorated due to exposure to plasma for a certain period of time, the surface may be polished again to remove the deteriorated portion in order to reuse the structural member. In other words, the surface of the deteriorated protective film may be refreshed. In the structural member with the above configuration, the high-hardness particles are dispersedly arranged not only on the surface of the protective film but also entirely inside it. Therefore, also upon refreshing, performing soft polishing while measuring the protruding amount of each high-hardness particle allows the protective film to be removed as much as necessary again in the same manner as above.

According to the present invention, a structural member capable of preventing a surface of a protective film from being polished more than necessary upon manufacturing, can be provided.

### BRIEF DESCRIPTION OF THE DRAWINGS

FIG. 1 shows a schematical diagram of a cross-section of the structural member according to the present embodiment;

FIG. 2 shows a diagram of a cross-section of a protective film of the structural member according to the present embodiment;

FIG. 3A and FIG. 3B show diagrams for explaining a method for producing the structural member according to the present embodiment; and

FIGS. 4A to 4C show a diagram for explaining the method for producing a structural member according to the present embodiment.

### DETAILED DESCRIPTION

The present embodiment will be described by referring to the attached drawings. In order to facilitate understanding of the description, an identical constituent is indicated with the same sign as far as possible in each drawing, and duplicated explanations will be omitted.

A structural member 10 according to the present embodiment is used as a member constituting an inner wall of a processing chamber in a semiconductor manufacturing apparatus (not shown), for example, such as a plasma etching apparatus. Note, however, the application of such structural member 10 is only an example, and should not be limited for the semiconductor manufacturing apparatus.

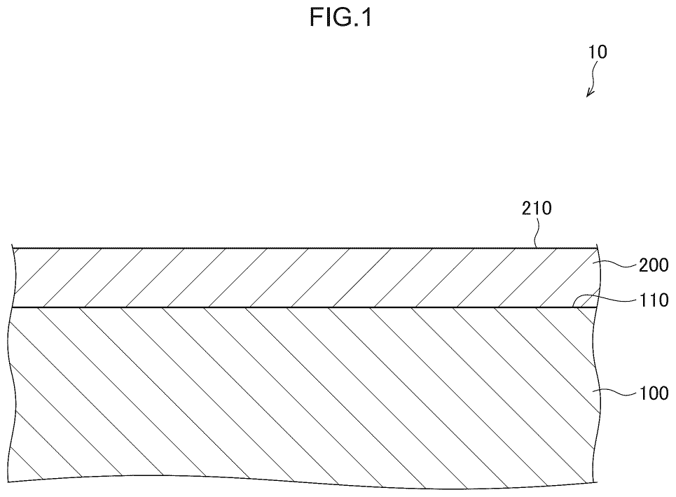

As shown in FIG. 1, the structural member 10 includes a base material 100 and a protective film 200. In a plasma etching apparatus and the like, a surface 210 of the protective film 200 is exposed toward a space in the chamber. The protective film 200 is arranged for the purpose of protecting a surface 110 of the base material 100 from plasma.

The base material 100 is a member that mostly occupies the entire structural member 10. In the present embodiment, the base material 100 is composed of a sintered ceramic body containing high-purity aluminum oxide (Al2O3), but may be made of a different type of ceramic or a member other than ceramic (for example, a metal member). The surface 110 of the base material 100 is a flat surface in the present embodiment, but the surface 110 may have a convex and concave structure, a slope, or the like.

As described above, the protective film 200 is a film formed to protect the base material 100 from plasma. The protective film 200 is formed so as to cover the entire surface 110 of the base material 100. In the present embodiment, the protective film 200 is composed of a film containing polycrystalline yttria (Y2O3) as a main component, but may be a ceramic film composed of a different material from the above material. A thickness of the protective film 200 is appropriately set depending on a length of period of time required to maintain durability or the like. In the present embodiment, the thickness of the protective film 200 is 10 μm.

The protective film 200 according to the present embodiment is formed on the surface 110 of the base material 100 after calcination by using an aerosol deposition method. As is well known, in an aerosol deposition method, microparticles that are materials for the protective film 200, are dispersed in gas to form an “aerosol,” which is then injected through a nozzle and brought into collision toward the surface 110. On the surface 110, deformation and crushing of the microparticles result from the impact of collision, thereby allowing the microparticles to be gradually deposited as the protective film 200 while bonded with each other. The protective film 200 may be a film formed by other deposition methods.

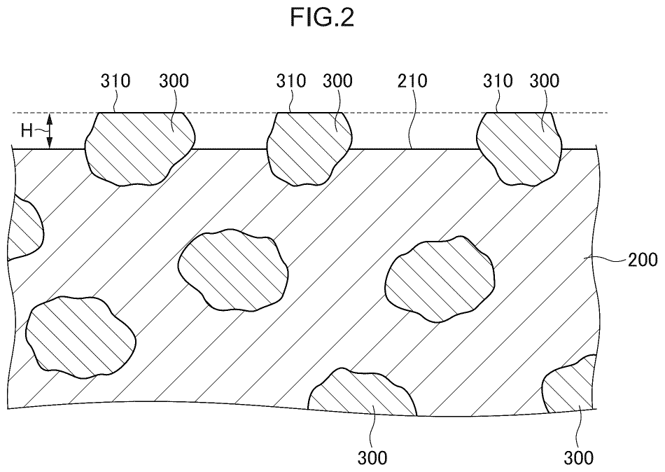

FIG. 2 depicts a cross-section of the protective film 200 in more detail. As shown in the figure, a plurality of particles 300 are dispersedly arranged inside the protective film 200. In the present embodiment, the particle 300 is formed by a material composed of alumina as a main component. Therefore, the hardness of the particle 300 (alumina) is higher than that of the protective film 200 (yttria) in the circumference of the particle. Each particle 300 corresponds to a “high-hardness particle” in the present embodiment.

The particle 300 may be formed by other material provided that its hardness is higher than the hardness of the protective film 200. In a case in which the main component of the protective film 200 is yttria, as in the present embodiment, the particle 300 may be formed of, for example, a material containing yttrium, aluminum, and garnet (YAG). Using such a composite material can enhance the mechanical strength of the entire protective film 200 including the particles 300.

The arrangement density of the particle 300, i.e., the number of particles 300 contained per unit volume of the protective film 200, is generally uniform in the entire protective film 200. Most of the particles 300 in their entirety are embedded inside the protective film 200, but a plurality of particles 300 partially protrude outwardly from the surface 210 of the protective film 200.

A distance from the surface 210 of the protective film 200 to a tip of the protruding particle 300 (a distance along a direction perpendicular to the surface 210) is hereafter defined as the “protruding amount H” of the particle 300. In the present embodiment, the protruding amount H of each particle 300 protruding from the surface 210 is uniform. A method for making each protruding amount H uniform will be described below. The protruding amount H may be generally uniform, and may, for example, vary within a range of approximately 10% of its average value.

As shown in FIG. 2, the tip 310 of each particle 300 protruding from the surface 210 of the protective film 200 is a flat surface parallel to the surface 210.

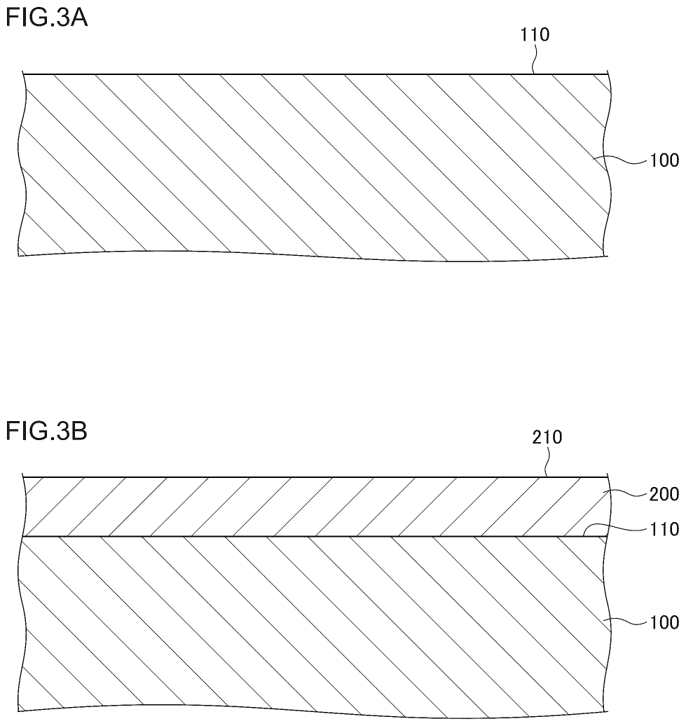

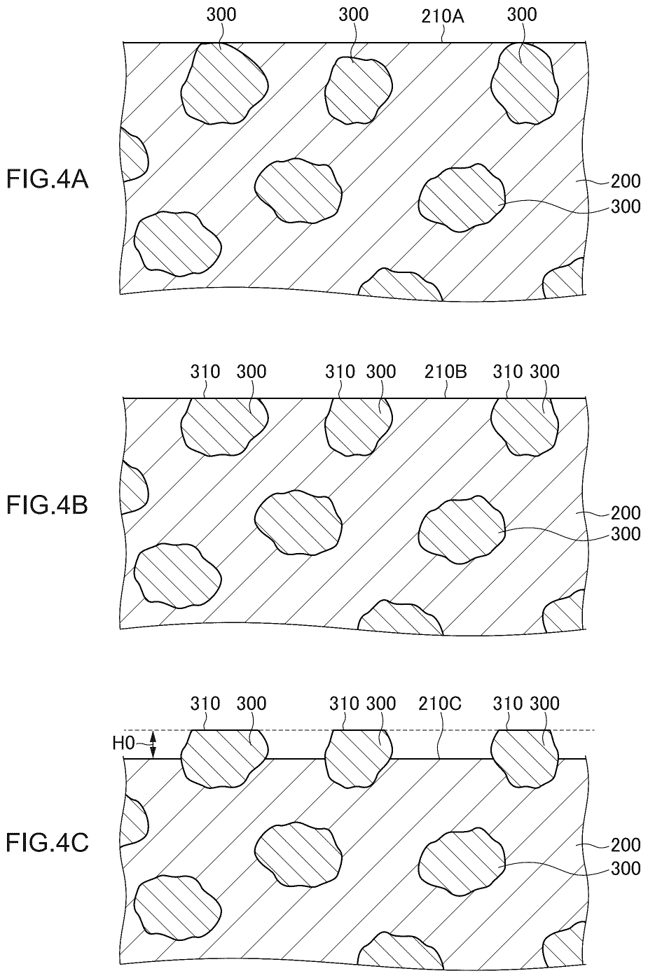

A method for producing the structural member 10 will be described with reference to FIG. 3A, FIG. 3B and FIGS. 4A to 4C. First, as shown in FIG. 3A, the base material 100 is provided. It is preferable that the surface 110 of the base material 100 has been preliminarily adjusted for surface roughness thereof, and the like to the extent that the protective film 200 can be stably formed.

Subsequently, as shown in FIG. 3B, the protective film 200 is formed so as to cover the surface 110 of the base material 100. The protective film 200 of the present embodiment is formed by using the aerosol deposition method as described before.

In the present embodiment, the microparticles that are materials of the protective film 200 are preliminarily mixed with the particles 300 in a predetermined proportion and sufficiently mixed so that the distribution of the particles is uniform. The mixture of particles thus obtained is dispersed in gas to form an “aerosol,” which is then injected through a nozzle and brought into collision toward the surface 110. Therefore, at a point of time of completion of film deposition by the aerosol deposition method, as shown in FIG. 4A, the particles 300 are in the state of being dispersedly arranged inside the protective film 200. At this point of time, almost no particles 300 protruding from the surface 210A of the protective film 200 are present. The entire surface 210A is a flat surface, and all the particles 300 are embedded at the deeper side of the surface.

Subsequently, the entire surface 210A in FIG. 4A is then polished to adjust it for its flatness. FIG. 4B schematically shows the state of the surface after polishing. A surface that newly appeared after the surface 210A in FIG. 4A has been polished, is also marked as a “surface 210B” below. The amount of protective film 200 removed until the surface 210A becomes surface 210B is approximately from 1.0 μm to 2.5 μm. A grinding stone made of diamond is used for polishing at this time. Therefore, the particles 300 in the vicinity of a surface layer of the protective film 200 are polished together with the protective film 200, making the upper edge in the figure a flat surface. This flat surface is a portion to be the tip 310 in FIG. 2. At a point of time in FIG. 4B, the tip 310 is on the same plane as the surface 210B.

The above polishing performed to achieve the state shown in FIG. 4B is also referred to as “hard polishing” below in order to distinguish it from soft polishing, which will be described next. The amount of protective film 200 removed in hard polishing is relatively large, ranging from approximately 1.0 μm to 2.5 μm as described above, and can be measured with a spectroscopic reflectometry film thickness meter. Hard polishing is performed while the amount of removal is measured each time, and hard polishing may be terminated when the amount of removal reaches the preset target value that has been preliminarily set. A grinding stone used for hard polishing may be diamond, as described above, or Sic or CBN (Cubic Boron Nitride), for example.

In hard polishing, the protective film 200 is scraped relatively large, leaving residual stress on the surface 210B after polishing. Such residual stress can cause a lowering of durability of the protective film 200 and the generation of particles. Therefore, in order to release the residual stress on the surface 210B, it undergoes soft polishing following hard polishing. The “soft polishing” refers to polishing the surface 210B of the protective film 200 with as little residual stress generated as possible, for example, by using a soft member such as polishing cloth or by chemical etching.

A thickness of a surface layer portion to be removed by soft polishing is very thin, which is as thin as 100 nm at most. When a thickness thicker than this is removed, the durability of the protective film 200 will be needlessly reduced, which is not preferable. Therefore, upon performing soft polishing, the polishing may be performed while confirming how much thickness has been removed from the surface 210B of the protective film 200 each time.

As a method for confirming a thickness removed, there is considered to be a method for measuring the entire thickness of the protective film 200 each time using, for example, a spectroscopic reflectometry film thickness meter to calculate the amount of change. However, it is difficult to accurately measure a change in thickness as thin as 100 nm or less using the spectroscopic reflectometry film thickness meter. Therefore, upon performing soft polishing in a conventional configuration, a surface layer portion of the protective film 200 has had to be excessively removed in excess of the minimum thickness to be removed.

Then, in the present embodiment, the particles 300 are dispersedly arranged inside the protective film 200 as described above, thereby making it easier to measure the amount of removal. FIG. 4C schematically shows the state of the protective film 200 in the course of soft polishing. While undergoing soft polishing, the protective film 200 is gradually removed from the surface. Therefore, the surface 210B shown in FIG. 4B gradually recedes toward the base material 100 side (downward in FIG. 4). The surface that gradually recedes in this manner from the state of FIG. 4B is also referred to as a “surface 210C” below.

As the particle 300 has higher hardness than the protective film 200, on the other hand, it is hardly removed even when undergoing soft polishing and generally remains in its initial shape. Therefore, as shown in FIG. 4C, all of the particles 300 that had a flat tip 310 are in the state of protrusion outward from the surface 210C. The protruding amount H0 of the particles 300 protruding from the surface 210C is mostly the same as the thickness of the protective film 200 that has been removed so far (the above amount removed).

The protruding amount H0 of the particles 300 can be measured relatively easily and precisely using a measuring apparatus such as an electric micrometer, for example. Therefore, performing soft polishing while measuring the protruding amount H0, i.e., the amount of protective film 200 removed each time allows a surface layer portion to be removed as much as necessary. In other words, it is possible to prevent the surface 210 of the protective film 200 from being polished more than necessary. At a point of time when the protruding amount H0 of the particles 300 reaches the preset target amount of removal that has been preliminarily set, soft polishing may be terminated. The surface 210C at this time becomes the surface 210 in FIG. 2. The protruding amount H0 at this time is also the same as the protruding amount H in FIG. 2.

In the course of soft polishing, the tip 310 of each particle 300 protruding from the surface 210C of the protective film 200 is a flat surface parallel to the surface 210C. Therefore, measurement of the protruding amount H0 using an electric micrometer or the like can be easily and accurately made.

The protruding amount H0 of the particle 300 may be measured directly using an electric micrometer or the like, or it may be estimated or calculated by other methods. For example, in the course of soft polishing, the surface 210C may be photographed from its top view, and the protruding amount H0 of particle 300 may be estimated or calculated based on a size of each particle 300 in the obtained image.

Soft polishing is performed uniformly on the entire surface 210B shown in FIG. 4B. Therefore, the protruding amount H0 of each particle 300, i.e., the amount of protective film 200 removed, is generally uniform throughout the entire surface. In order to make the amount of protective film 200 removed more uniform, soft polishing may be partially performed, if necessary, while the protruding amount H0, i.e., the amount of protective film 200 removed is measured at a plurality of locations of the surface 210C individually.

In soft polishing, as shown in FIG. 4C, the particles 300 are hardly removed, so that the protruding amount H0 of particles 300 measured can be taken as the amount of protective film 200 removed as is. However, depending on a material of the particle 300, there may also be a case where change in shape of the particle 300 due to soft polishing cannot be ignored. Even in such a case, there is a certain correlation between the protruding amount H0 of particle 300 measured and the amount of protective film 200 removed. Therefore, provided that the correlation has been preliminarily known through experiments or the like, the amount of removal can be easily and accurately calculated based on the protruding amount H0.

After the structural member 10 was attached to an etching apparatus or the like, and a surface 210 of the protective film 200 has been deteriorated due to exposure to plasma for a certain period of time, the surface 210 may be polished again to remove the deteriorated portion in order to reuse the structural member 10. Namely, the surface 210 may be refreshed.

The particles 300 are dispersedly arranged not only on the surface 210 of the protective film 200 but also entirely inside it. Therefore, also upon refreshing, performing soft polishing while measuring the protruding amount H0 of each particle 300 allows the protective film 200 to be removed as much as necessary again in the same manner as above.

So far, the present embodiments have been described with reference to specific examples. However, the present disclosure is not limited to these specific examples. Design changes appropriately made to these specific examples by those skilled in the art are also included in the scope of the present disclosure as long as they include the features of the present disclosure. Each element included in each of the aforementioned specific examples, as well as their arrangement, conditions, shapes, and the like, are not limited to those exemplified, and can be appropriately changed. Each element included in each of the aforementioned specific examples can be appropriately combined as long as no technical inconsistency thereof results.

What is claimed is:

1. A structural member comprising a base material and a protective film covering a surface of the base material,
wherein a high-hardness particle that is harder than the protective film is dispersedly arranged inside the protective film.

2. The structural member according to claim 1, wherein a plurality of the high-hardness particles protrude from a surface of the protective film.

3. The structural member according to claim 2, wherein the protruding amount of each high-hardness particle from a surface of the protective film is uniform.

4. The structural member according to claim 3, wherein a tip of each high-hardness particle protruding from a surface of the protective film is a flat surface parallel to the surface of the protective film.

5. The structural member according to claim 1, wherein the protective film comprises yttria, and the high-hardness particle comprises alumina.

6. The structural member according to claim 1, wherein the protective film comprises yttria, and the high-hardness particle comprises yttrium, aluminum, and garnet.
